(19) United States
(12) Patent Application Publication
(10) Pub. No.: US 2026/0106434 A1
(43) Pub. Date: Apr. 16, 2026

(54) VERTICAL CAVITY SURFACE EMITTING SEMICONDUCTOR LASER AND METHOD FOR PRODUCING SAME

(71) Applicant: TRUMPF PHOTONIC COMPONENTS GMBH, Ulm (DE)

(72) Inventors: Holger Joachim MOENCH, Vaals (NL); Johanna Sophie KOLB, Aachen (DE); Andre MAASSDORF, Berlin (DE); Markus WEYERS, Wildau (DE)

(21) Appl. No.: 19/420,797

(22) Filed: Dec. 16, 2025

Related U.S. Application Data
(63) Continuation of application No. PCT/EP2024/067295, filed on Jun. 20, 2024.

(30) Foreign Application Priority Data
Jun. 21, 2023 (DE) 10 2023 116 268.3

(51) Int. Cl. H01S 5/183; H01S 5/30; H01S 5/34

(52) U.S. Cl. CPC H01S 5/18311; H01S 5/3054; H01S 5/34

(57) ABSTRACT

A vertical cavity surface emitting semiconductor laser includes a multi-layered semiconductor structure having an optical resonator composed of semiconductor layers, the optical resonator includes a first Bragg mirror, a second Bragg mirror, and an active region between the first Bragg mirror and the second Bragg mirror for generating laser radiation. The active region has a plurality of active layers including a first and at least a second active layer, where the second active layer is a last active layer in front of the second Bragg mirror. A first oxide aperture for current constriction and a first tunnel diode are located between the first active layer and the second active layer, a second oxide aperture is located on a side of the second active layer which is remote from the first active layer. A second tunnel diode is located on the side of the second active layer.

### CROSS REFERENCE TO RELATED APPLICATIONS

This application is a continuation of International Application No. PCT/EP2024/067295 (WO 2024/261155 A1), filed on Jun. 20, 2024, and claims benefit to German Patent Application No. DE 10 2023 116 268.3, filed on Jun. 21, 2023. The aforementioned applications are hereby incorporated by reference herein.

### FIELD

The invention relates to a vertical cavity surface emitting a semiconductor laser which has a multi-layered semiconductor structure having an optical resonator composed of semiconductor layers, wherein the optical resonator comprises a first Bragg mirror, a second Bragg mirror, and an active region between the first Bragg mirror and the second Bragg mirror for generating laser radiation.

### BACKGROUND

Vertical cavity surface emitting semiconductor lasers, referred to as VCSELs, are used, for example, as radiation sources in sensors or in communications technology. VCSELs typically have a multi-layered semiconductor structure in which semiconductor layers are grown epitaxially on a semiconductor substrate in a stacked arrangement. The multi-layered semiconductor structure typically comprises a first Bragg mirror, an active region, and a second Bragg mirror, which together form an optical resonator. A Bragg mirror is also referred to as a DBR (distributed Bragg reflector). VCSELs typically have an oxidized region in the optical resonator, which has a semiconductor layer which is oxidized to a certain oxidation extent to form a current aperture in the resonator, also referred to as an oxide aperture. The semiconductor layer intended for oxidation is, for example, a layer having a high AIAs (aluminum arsenide) content, which can be selectively oxidized to Aluminum Oxide (AI₂O₃) up to a predetermined oxidation extent.

VCSELs are known which have an active region having a plurality of active layers, wherein a tunnel diode is located between adjacent active layers. For example, such a structure can have three active layers and two tunnel diodes. With such an arrangement, the output power of the VCSEL can be significantly increased, in pulsed operation even to three times its value, for example. In other words, with such an arrangement, 3x the photons can be generated from one charge carrier. In such a design of the optical resonator with a plurality of active layers, an oxide aperture is required near each active layer to channel or constrict the current. To produce the oxide aperture, a layer having a high content of aluminum arsenide (AIAs), for example a content of 90-100% AIAs, is typically used. It has been found that the incorporation of tunnel diodes between the active layers changes the crystal properties of the layers intended for oxidation, for example inducing intrinsic defects such as vacancies, and thereby changes the oxidation rate of the oxidizable layer(s), which undesirably results in current apertures of different sizes. In other words, when tunnel diodes are installed, the oxidation rates of the oxidizable layers differ significantly from the situation without tunnel diodes. This effect is particularly pronounced in oxide apertures located near a tunnel diode, whereas an oxide aperture not located near a tunnel diode oxidizes significantly faster.

US 2021/0104872 A1 describes various designs of VCSELs which have one or more tunnel diodes in the multi-layered semiconductor structure. An n-doped semiconductor layer of the tunnel diode is doped with at least one element in such a way that not only does the tunnel diode have a high doping concentration, but the oxidation rate is relatively stable during the oxidation process. Alternatively, the n-doped semiconductor layer is doped with at least two elements. The tunnel diode is located between two active layers of the VCSEL. The solution approach described in this document for achieving a uniform oxidation rate when oxidizing the oxidizable layer(s) is based on additional doping and layers, which, however, increase the complexity of producing the VCSEL.

### SUMMARY

In an embodiment, the present disclosure provides a vertical cavity surface emitting semiconductor laser includes a multi-layered semiconductor structure having an optical resonator composed of semiconductor layers, the optical resonator includes a first Bragg mirror, a second Bragg mirror, and an active region between the first Bragg mirror and the second Bragg mirror for generating laser radiation. The active region has a plurality of active layers including a first and at least a second active layer, where the second active layer is a last active layer in front of the second Bragg mirror. A first oxide aperture for current constriction and a first tunnel diode are located between the first active layer and the second active layer, a second oxide aperture is located on a side of the second active layer which is remote from the first active layer. A second tunnel diode is located on the side of the second active layer which is remote from the first active layer.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic longitudinal section through a VCSEL according to a first exemplary embodiment; and

FIG. 2 shows a schematic longitudinal section through a VCSEL according to a second exemplary embodiment.

### DETAILED DESCRIPTION

The present disclosure provides a vertical cavity surface emitting semiconductor laser in which the oxidation rate of all existing oxidizable layers for the production of oxide apertures is uniform, and thus a uniform oxidation extent of all oxide apertures is ensured, while keeping the complexity of producing the VCSEL low.

The present disclosure also provides a method for producing a vertical cavity surface emitting semiconductor laser.

The vertical cavity surface emitting semiconductor laser according to the present disclosure, hereinafter referred to as VCSEL, has an active region having a plurality of active layers comprising a first and at least a second active layer. The second active layer is the last active layer in front of the second Bragg mirror. A first oxide aperture for current constriction and a first tunnel diode are located between the first active layer and the second active layer, wherein a second oxide aperture is located on a side of the second active layer which is remote from the first active layer. This basic structure is advantageous, as described above, because the VCSEL, by virtue of the at least two active layers with a tunnel diode between these active layers, allows for a higher light output.

To solve the problem of different oxidation rates during production of the first oxide aperture and the second oxide aperture, the VCSEL according to the present disclosure has a second tunnel diode on the side of the second active layer which is remote from the first active layer. The additional (second) tunnel diode on the side of the second active layer which is remote from the first active layer ensures that the environment of each oxide aperture can be designed identically. Experiments have shown that, owing to the additional tunnel diode, the oxidation rates during production of the oxide apertures become equalized and the VCSEL can be fabricated without elaborate additional measures. A fine adjustment of the composition and special control of the oxidation rates, both of which prove to be difficult, are not required in the production of the VCSEL according to the present disclosure. Rather, the present disclosure solves the problem of different oxidation rates by increasing the symmetry of the arrangement of the active layers, the oxide apertures and the tunnel diode by means of an additional tunnel diode.

The possible disadvantage of a slightly longer growth time and slightly increased absorption due to the additional tunnel diode is more than compensated for by the significantly simplified and more easily controlled production of the VCSEL.

The first Bragg mirror may be the substrate-side Bragg mirror or the Bragg mirror which is remote from the substrate, regardless of the fact that, in the following description, the first Bragg mirror is described as the substrate-side Bragg mirror.

In an exemplary embodiment, the layer sequence of the arrangement consisting of the second active layer, the second oxide aperture and the second tunnel diode is the same as the layer sequence of the arrangement consisting of the first active layer, the first oxide aperture and the first tunnel diode.

In this embodiment, a particularly high symmetry of the arrangement of the active layers, the oxide apertures and the tunnel diodes is created, which results in particularly good equalization of the oxidation rates in the first and the second oxidizable layer for the production of the first and the second oxide aperture and thus uniform current apertures.

An advantageous sequence, when viewed from the first Bragg mirror of the first active layer, is: first active layer—first oxide aperture—first tunnel diode—second active layer—second oxide aperture—second tunnel diode. Another possible sequence is: first active layer—first tunnel diode—first oxide layer—second active layer—second tunnel diode—second oxide layer.

Preferably, the first and the second tunnel diode each have a highly doped n-layer and a highly doped p-layer having a doping of at least 1E19 cm⁻³, wherein preferably the p-doped layer of the second tunnel diode faces the second active layer and the n-doped layer of the second tunnel diode faces the second Bragg mirror.

Due to high doping, the first and the second tunnel diode advantageously have a very low resistance. As is customary with tunnel diodes, the first and the second tunnel diode are operated in reverse bias. The highly doped n-layer and the highly doped p-layer are very thin layers compared to the other layers of the multi-layered semiconductor structure. Because the n-doped layer faces the second Bragg mirror, the second Bragg mirror becomes an n-Bragg mirror. In contrast to conventional VCSELs, where one Bragg mirror is an n-mirror and the other is a p-Bragg mirror, in the VCSEL according to the present disclosure, both Bragg mirrors are n-mirrors in this embodiment. Accordingly, an n-contact for supplying current to the VCSEL can be arranged on the second Bragg mirror. Although n-type contacting of both Bragg mirrors is unusual, this nevertheless has the advantage that optical losses are reduced in both mirrors rather than only one. n-type material absorbs approximately three times less laser light than p-type material at wavelengths of, for example, 940 nm.

In a further exemplary embodiment, the active region has at least a third active layer which is located on the side of the first active layer which is remote from the second active layer, and wherein a third oxide aperture and a third tunnel diode are located between the third and the first active layer.

In this embodiment, the VCSEL has a total of three active layers, three oxide apertures and three tunnel diodes, with the aforementioned advantages of high light output of the VCSEL with simultaneously uniform oxidation rates and thus uniform current apertures in the oxide apertures.

In the context of the aforementioned embodiment, the layer sequence of the arrangement consisting of the third active layer, the third oxide aperture and the third tunnel diode is preferably the same as the layer sequence of the arrangement consisting of the first active layer, the first oxide aperture and the first tunnel diode.

In this embodiment, the symmetry is further increased even when the active region is designed with three active layers, and the oxidation rates in the oxidizable layers are matched to one another as far as possible.

It is understood that the active region may contain more than three active layers, more than three oxide apertures and/or more than three tunnel diodes.

Preferably, the first and the second and, if applicable, the third tunnel diode have GaAs (gallium arsenide) layers.

Furthermore, according to the present disclosure, a method for producing a vertical cavity surface emitting semiconductor laser is provided.

According to the method, a multi-layered semiconductor structure is produced having an optical resonator composed of semiconductor layers, wherein the optical resonator comprises a first Bragg mirror, a second Bragg mirror and an active region between the first Bragg mirror and the second Bragg mirror for generating laser radiation, wherein the active region has a plurality of active layers comprising a first and at least a second active layer, wherein the second active layer is the last active layer in front of the second Bragg mirror. The multi-layered semiconductor structure is produced according to the present disclosure such that a first oxidizable layer and a first tunnel diode are located between the first active layer and the second active layer, and a second oxidizable layer is located on a side of the second active layer which is remote from the first active layer, and a second tunnel diode is located on the side of the second active layer which is remote from the first active layer. The first and the second oxidizable layer are oxidized to generate a first oxide aperture and a second oxide aperture for current constriction.

The method according to the present disclosure has the same advantages as the VCSEL according to the present disclosure. Likewise, the method according to the present disclosure has preferred embodiments corresponding to the preferred embodiments of the VCSEL according to the present disclosure.

Further features and advantages can be found in the following description and the attached drawings.

It is understood that the features mentioned above and those to be explained below can be used not only in the combination specified in each case, but also in other combinations or on their own without departing from the scope of the present disclosure.

An exemplary embodiment of the present disclosure is shown in the drawings and is described in more detail below with reference thereto.

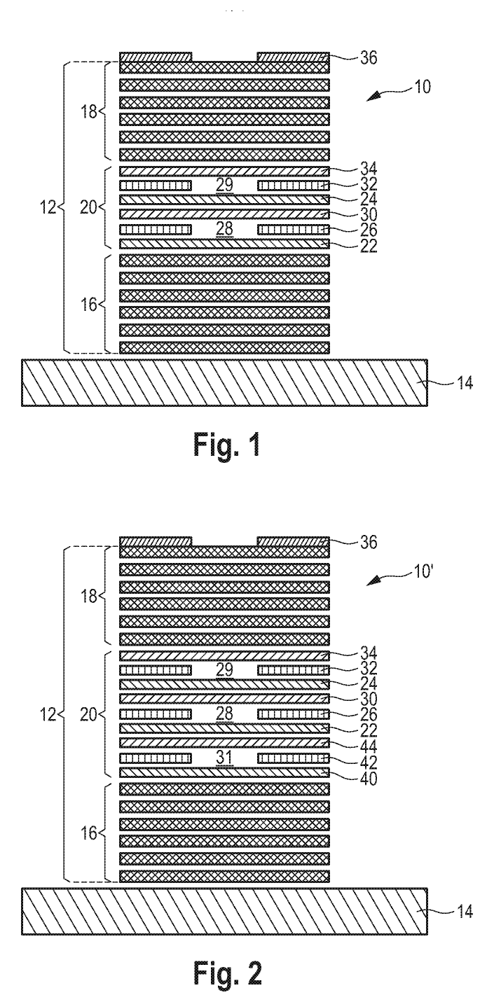

FIG. 1 shows a vertical cavity surface emitting semiconductor laser, referred to as VCSEL, denoted by the general reference sign 10. The VCSEL 10 has a multi-layered semiconductor structure having an optical resonator 12 composed of semiconductor layers. The semiconductor layers of the optical resonator 12 are located on a substrate 14, which is likewise made of a semiconductor material. In the finished VCSEL 10, the substrate 14 may also have been removed. The semiconductor layers of the optical resonator 12 are grown on the substrate 14 by means of epitaxy, as is known to a person skilled in the art.

The optical resonator 12 has a first Bragg mirror 16 and a second Bragg mirror 18. The first Bragg mirror 16 and the second Bragg mirror 18 are also referred to as DBRs (distributed Bragg reflectors). Each of the two Bragg mirrors 16 and 18 is formed from a sequence of semiconductor layer pairs, wherein each pair has one layer having a higher refractive index and one layer having a lower refractive index.

The optical resonator 12 has an active region 20 between the first Bragg mirror 16 and the second Bragg mirror 18. The active region 20 is used to generate laser radiation. The active region 20 has a first active layer 22 and a second active layer 24. The first active layer 22 faces the first Bragg mirror 16, and the second active layer 24 is located closer to the second Bragg mirror 18. The second active layer 24 forms the last active layer in front of the second Bragg mirror 18. The active layers 22 and 24 may each be designed as multiple quantum well structures (MQWs).

A first oxide aperture 26 is located between the first active layer 22 and the second active layer 24. The oxide aperture 26 is formed from a layer which is easily oxidized. For example, a layer having a high content of aluminum arsenide (AIAs) is a material which is easily and controllably oxidizable. The oxidation of the layer occurs up to a predetermined oxidation extent such that a central region 28 of the oxide aperture 26 is not oxidized. The central region 28 thus forms an aperture through which the current passes to drive the active region 20, whereas the oxidized outer region of the layer acts in an insulating manner. The oxide aperture 26 thus serves to constrict the current.

Adjacent to, in particular immediately adjacent to, the first oxide aperture 26 is a first tunnel diode 30. The tunnel diode 30 between the first active layer 22 and the second active layer 24 increases the light output from the two active layers 22 and 24. Adjacent to, in particular immediately adjacent to, the second active layer 24 is a second oxide aperture 32, which is identical to the first oxide aperture 26 in terms of its material composition and function. The second oxide aperture 32 has a central region 29 which acts as a current aperture. The second oxide aperture 32 is followed by a second tunnel diode 34 which has the same material composition as the first tunnel diode 30.

It has been found that, without the additional or second tunnel diode 34, the oxidation rate during the production of the second oxide aperture 32 is significantly higher than the oxidation rate during the production of the first oxide aperture 26. Without the second tunnel diode 34, the apertures in the respective central regions 28 and 29 would therefore be of different sizes. Experiments have shown that, during production of the first oxide aperture 26 and the second oxide aperture 32, the oxidation rates are matched to one another when the second tunnel diode 34 is present in the multi-layered semiconductor structure. By the provision of the second tunnel diode 34, the symmetry of the layer structure in the region of the oxide apertures 26 and 32 is increased; in other words, the environment of the second oxide aperture 32 looks the same as the environment of the first oxide aperture 26 due to the additional tunnel diode 34.

The first tunnel diode 30 and the second tunnel diode 34 may each be composed of two thin layers, of which one is a highly doped p-layer and the other is a highly doped n-layer. The p-doped layer in question faces the first Bragg mirror 16, and the n-doped layer faces the second Bragg mirror 18. Due to the additional provision of a second tunnel diode 34, the second Bragg mirror 18 becomes an n-Bragg mirror.

A top-side contact 36 for contacting the VCSEL 10 is accordingly an n-contact. The highly doped n-layers and the highly doped p-layers of the first tunnel diode 30 and the second tunnel diode 34 may each have a doping of at least 1E19 cm⁻³.

In the VCSEL 10, the first Bragg mirror 16 and the second Bragg mirror 18 are therefore n-doped mirrors.

The layer sequence of the arrangement consisting of the second active layer 24, the second oxide aperture 32 and the second tunnel diode 34 is the same as the layer sequence of the arrangement consisting of the first active layer 22, the first oxide aperture 26 and the first tunnel diode 30. In the exemplary embodiment shown in FIG. 1, the active region 20, when viewed from the first Bragg mirror, has the layer sequence first active layer 22—first oxide aperture 26—first tunnel diode 30—second active layer 24—second oxide aperture 32—second tunnel diode 34. The sequence of first oxide aperture 26—first tunnel diode 30 may also be reversed, in which case the sequence of second oxide aperture 32—second tunnel diode 34 is preferably also reversed.

The first tunnel diode 30 and the second tunnel diode 34 are composed of gallium arsenide (GaAs) layers, for example, which are very thin. For example, they may have a thickness of 10-30 nm. Carbon can be used as the dopant for the highly doped p-layers of the tunnel diodes 30 and 34, and tellurium can be used for the highly doped n-layers of the tunnel diodes 30 and 34.

In this exemplary embodiment, the second Bragg mirror serves to couple out the generated laser radiation. For this purpose, the contact 36 can be designed as a ring contact. The number of semiconductor layer pairs of the first Bragg mirror 16 is greater than the number of semiconductor layer pairs of the second Bragg mirror 18. For example, the first Bragg mirror may have forty pairs of mirrors, and the second Bragg mirror 18 may have fewer than twenty pairs of mirrors. The uppermost layer of the second Bragg mirror, or an additional layer on the second Bragg mirror 18, may be designed as an n-doped contact layer.

In a specific example, the multi-layered semiconductor structure of the VCSEL 10 may be composed as follows: the multi-layered semiconductor structure may be based on the aluminum gallium arsenide/gallium arsenide (AIGaAs/GaAs) material system. The substrate 14 may be a gallium arsenide substrate, including an n-doped nucleation layer. The first active layer 22 and the second active layer 24 may be designed as multiple quantum well structures (MQWs). The oxide apertures 26 and 32 may be produced from semiconductor layers having a high aluminum content, in particular aluminum arsenide (AIAs). The first tunnel diode 30 and the second tunnel diode 34 may each be formed from two thin, highly doped gallium arsenide layers, wherein, when viewed from the substrate 14, the first is p-doped and the second is n-doped. The doping is preferably more than 1E19 cm⁻³, for example 1E20 cm⁻³. For example, carbon is the dopant for the p-doped layers of the tunnel diodes 30 and 34, and tellurium is the dopant for the n-doped layers of the tunnel diodes 30 and 34. The second Bragg mirror 18 is composed of n-doped semiconductor layers, wherein the second Bragg mirror has, for example, fewer than twenty mirror pairs for coupling out the laser radiation. An n-doped contact layer may be located on the second Bragg mirror 18. The contact 36 is designed as a metal contact.

FIG. 2 shows a further exemplary embodiment of a VCSEL 10', wherein elements of the VCSEL 10' which are identical, similar or comparable to elements of the VCSEL 10 in FIG. 1 are provided with the same reference signs as in FIG. 1.

In the following, only the differences between the VCSEL 10' and the VCSEL 10 are described.

The active region 20 of the VCSEL 10' additionally has a third active layer 40, which is located on the side of the first active layer 22 which is remote from the second active layer 24. The VCSEL 10' thus has a total of three active layers, each of which may be designed as multiple quantum well structures. A third oxide aperture 42 and a third tunnel diode 44 are located between the third active layer 40 and the first active layer 22. The oxide aperture 42 has a central region 31 which acts as a current aperture.

The layer sequence of the arrangement consisting of the third active layer 40, the third oxide aperture 42 and the third tunnel diode 44 is preferably the same as the layer sequence of the arrangement consisting of the first active layer 22, the first oxide aperture 26 and the first tunnel diode 30. Overall, this results in a VCSEL having stacked p-n junctions or in a VCSEL having multiple active layers, here having a total of three active layers with high overall symmetry of the layer arrangement in the active region. Without the additional tunnel diode 34, experiments have shown that different oxidation rates would occur during production of the oxide apertures 26, 32 and 42. It has been found that, without the additional tunnel diode 34, the oxidation rates during production of the oxide apertures 42 and 26 are lower than the oxidation rate during production of the oxide aperture 32. This changes due to the additional tunnel diode 34 and the resulting higher symmetry of the arrangement. With the additional tunnel diode 34, the same oxidation rates are obtained during production of all of the oxide apertures 32, 26 and 42, and current apertures of the same size are formed in the respective central regions 28, 29, 31 of the oxide apertures 26, 32, 42.

In a method for producing the VCSEL 10 or 10', the semiconductor layers of the first Bragg mirror, the semiconductor layers of the active region 20 and the semiconductor layers of the second Bragg mirror 18 are grown on the substrate 14 by means of epitaxy. The layers used to produce the oxide apertures 26 and 32 or 42 are oxidized in a later method step to produce the oxide apertures 26 and 32 or 42. The contact 36 is then applied to the multi-layered semiconductor structure.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A vertical cavity surface emitting semiconductor laser, comprising;
a multi-layered semiconductor structure having an optical resonator composed of semiconductor layers,
wherein the optical resonator comprises:
a first Bragg mirror;
a second Bragg mirror; and
an active region between the first Bragg mirror and the second Bragg mirror for generating laser radiation,
wherein the active region has a plurality of active layers comprising a first and at least a second active layer,
wherein the second active layer is a last active layer in front of the second Bragg mirror,
wherein a first oxide aperture for current constriction and a first tunnel diode are located between the first active layer and the second active layer,
wherein a second oxide aperture is located on a side of the second active layer which is remote from the first active layer, and
wherein a second tunnel diode is located on the side of the second active layer which is remote from the first active layer.

2. The vertical cavity surface emitting semiconductor laser according to claim 1, wherein a layer sequence of an arrangement consisting of the second active layer, the second oxide aperture, and the second tunnel diode is the same as a layer sequence of an arrangement consisting of the first active layer, the first oxide aperture, and the first tunnel diode.

3. The vertical cavity surface emitting semiconductor laser according to claim 2, wherein, when viewed from the first Bragg mirror, the layer sequence of the arrangement consisting of the first and the second active layer, the first and the second oxide aperture, the first and the second tunnel diode is as follows: the first active layer—the first oxide aperture—the first tunnel diode—the second active layer—the second oxide aperture—the second tunnel diode.

4. The vertical cavity surface emitting semiconductor laser according to claim 1, wherein the first and the second tunnel diode each have a highly doped n-layer and a highly doped p-layer having a doping of at least 1E19 cm-3 wherein the highly doped p-layer of the second tunnel diode faces the second active layer and the highly doped n-layer of the second tunnel diode faces the second Bragg mirror.

5. The vertical cavity surface emitting semiconductor laser according to claim 1, wherein the first Bragg mirror and the second Bragg mirror are each an n-Bragg mirror.

6. The vertical cavity surface emitting semiconductor laser according to claim 1, wherein the active region has at least a third active layer which is located on a side of the first active layer which is remote from the second active layer, and wherein a third oxide aperture and a third tunnel diode are located between the third and the first active layer.

7. The vertical cavity surface emitting semiconductor laser according to claim 6, wherein a layer sequence of an arrangement consisting of the third active layer, the third oxide aperture, and the third tunnel diode is the same as a layer sequence of an arrangement consisting of the first active layer, the first oxide aperture, and the first tunnel diode.

8. A method for producing a vertical cavity surface emitting semiconductor laser, comprising the steps of:
producing a multi-layered semiconductor structure having an optical resonator composed of semiconductor layers, wherein the optical resonator comprises:
a first Bragg mirror;
a second Bragg mirror; and
an active region between the first Bragg mirror and the second Bragg mirror for generating laser radiation, wherein the active region has a plurality of active layers comprising a first and at least a second active layer, and wherein the second active layer is the last active layer in front of the second Bragg mirror,
wherein the multi-layered semiconductor structure is produced such that a first oxidizable layer and a first tunnel diode are located between the first active layer and the second active layer, and a second oxidizable layer is located on a side of the second active layer which is remote from the first active layer, and a second tunnel diode is located on the side of the second active layer which is remote from the first active layer, and
oxidizing the first and the second oxidizable layer to generate a first oxide aperture and a second oxide aperture for current constriction.
